(19) United States
(12) Patent Application Publication
(10) Pub. No.: US 2012/0132949 A1
(43) Pub. Date: May 31, 2012

(54) LED PACKAGE

(75) Inventors: Gen Watari, Fukuoka-ken (JP); Satoshi Shimizu, Fukuoka-ken (JP); Tetsuro Komatsu, Fukuoka-ken (JP)

(73) Assignee: KABUSHIKI KAISHA TOSHIBA, Tokyo (JP)

(21) Appl. No.: 13/234,755

(22) Filed: Sep. 16, 2011

(30) Foreign Application Priority Data
Nov. 25, 2010 (JP) 2010-262688

(51) Int. Cl. H01L 33/36

(52) U.S. Cl. 257/99; 257/E33.062

(57) ABSTRACT

According to one embodiment, an LED package includes mutually-separated first and second leadframes, an LED chip, and a resin body. One selected from the first leadframe and the second leadframe includes a base portion, and an extending portion. The base portion has an end surface covered with the resin body. The extending portion extends from the base portion and has an unevenness provided in a surface of the extending portion. A lower surface of the extending portion is covered with the resin body. A tip surface of the extending portion is exposed from the resin body. An exterior form of the resin body is used as an exterior form of the LED package.

### CROSS-REFERENCE TO RELATED APPLICATION

This application is based upon and claims the benefit of priority from Japanese Patent Application No. 2010-262688, filed on Nov. 25, 2010; the entire contents of which are incorporated herein by reference.

### FIELD

Embodiments described herein relate generally to an Light Emitting Diode (LED) package.

### BACKGROUND

In a conventional LED package in which an LED chip is mounted, a casing having a bowl-like configuration made of a white resin is provided, the LED chip is mounted on the bottom surface of the casing, and the LED chip is buried in the interior of the casing by encapsulating with a transparent resin to control the light distribution properties and increase the extraction efficiency of the light from the LED package. Often, casings have been formed of a polyamide-based thermoplastic resin.

However, in recent years, higher durability is needed for LED packages as the range of applications of LED packages increases. On the other hand, the light and the heat radiated from the LED chip increase as the output of the LED chip increases; and degradation of the resin portion that seals the LED chip progresses easily. Further, even lower costs are needed as the range of applications of LED packages increases.

### BRIEF DESCRIPTION OF THE DRAWINGS

FIG. 1 is a schematic perspective view of an LED package of an embodiment;

FIG. 2A is a schematic cross-sectional view of the LED package; and FIG. 2B is a bottom view of FIG. 2A;

FIG. 3A to FIG. 4C are schematic cross-sectional views illustrating specific examples of leadframes of the LED package of the embodiment;

FIG. 5 is a flowchart illustrating a method for manufacturing the LED package of the embodiment;

FIG. 6A to FIG. 8B are cross-sectional views of processes illustrating the method for manufacturing the LED package of the embodiment;

FIGS. 9A and 9B are plan views illustrating a leadframe sheet of the embodiment;

FIG. 10 is a perspective view illustrating an LED package according to another embodiment;

FIG. 11 is a perspective view illustrating an LED package according to yet another embodiment; and

FIG. 12 is a schematic cross-sectional view illustrating another specific examples of leadframes of the LED package of the embodiment.

### DETAILED DESCRIPTION

According to one embodiment, an LED package includes mutually-separated first and second leadframes, an LED chip, and a resin body. The first and second leadframes are disposed on a plane. The LED chip is provided above the first and second leadframes. One terminal of the LED chip is connected to the first leadframe, one other terminal of the LED chip is connected to the second leadframe. The resin body covers the LED chip. The resin body covers an upper surface, a portion of a lower surface and a portion of an end surface of the first leadframe, and an upper surface, a portion of a lower surface and a portion of an end surface of the second leadframe. A remaining portion of the lower surface and a remaining portion of the end surface of the first leadframe are exposed from the resin body. A remaining portion of the lower surface and a remaining portion of the end surface of the second leadframe are exposed from the resin body. One selected from the first leadframe and the second leadframe includes a base portion, and an extending portion. The base portion has an end surface covered with the resin body. The extending portion extends from the base portion and has an unevenness provided in a surface of the extending portion. A lower surface of the extending portion is covered with the resin body. A tip surface of the extending portion is exposed from the resin body. An exterior form of the resin body is used as an exterior form of the LED package.

Embodiments will now be described with reference to the drawings. Similar components in the drawings are marked with like reference numerals.

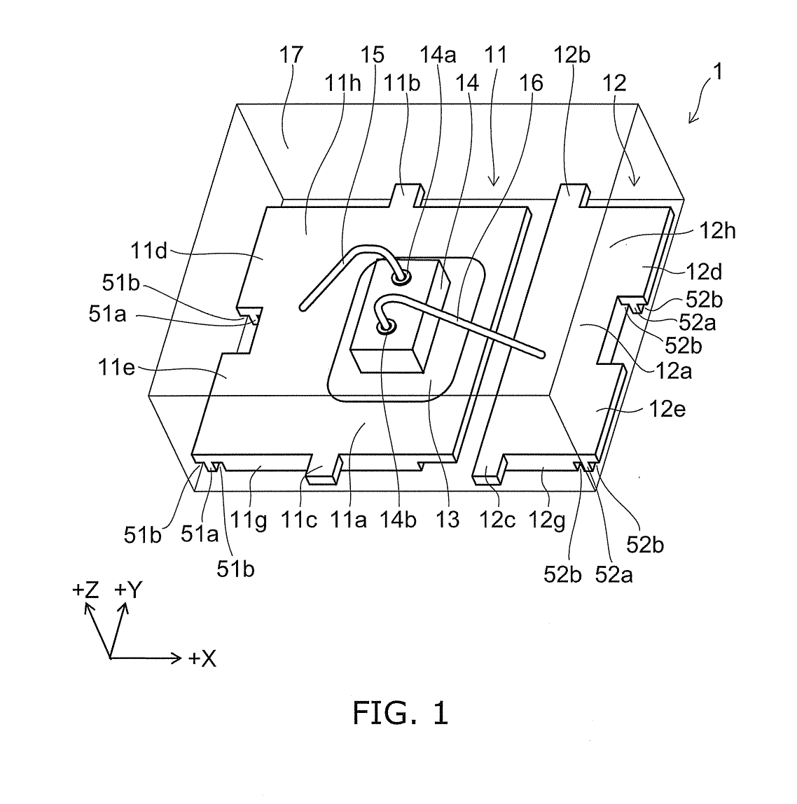

FIG. 1 is a schematic perspective view of an LED package 1 of the embodiment.

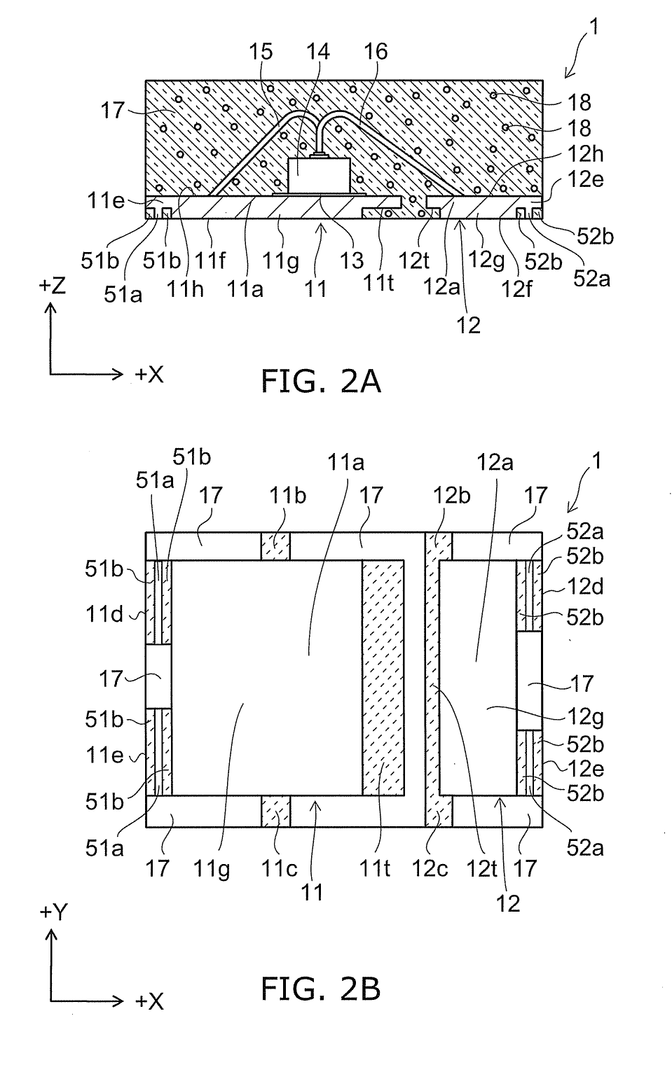

FIG. 2A is a schematic cross-sectional view of the LED package 1; and FIG. 2B is a bottom view of FIG. 2A.

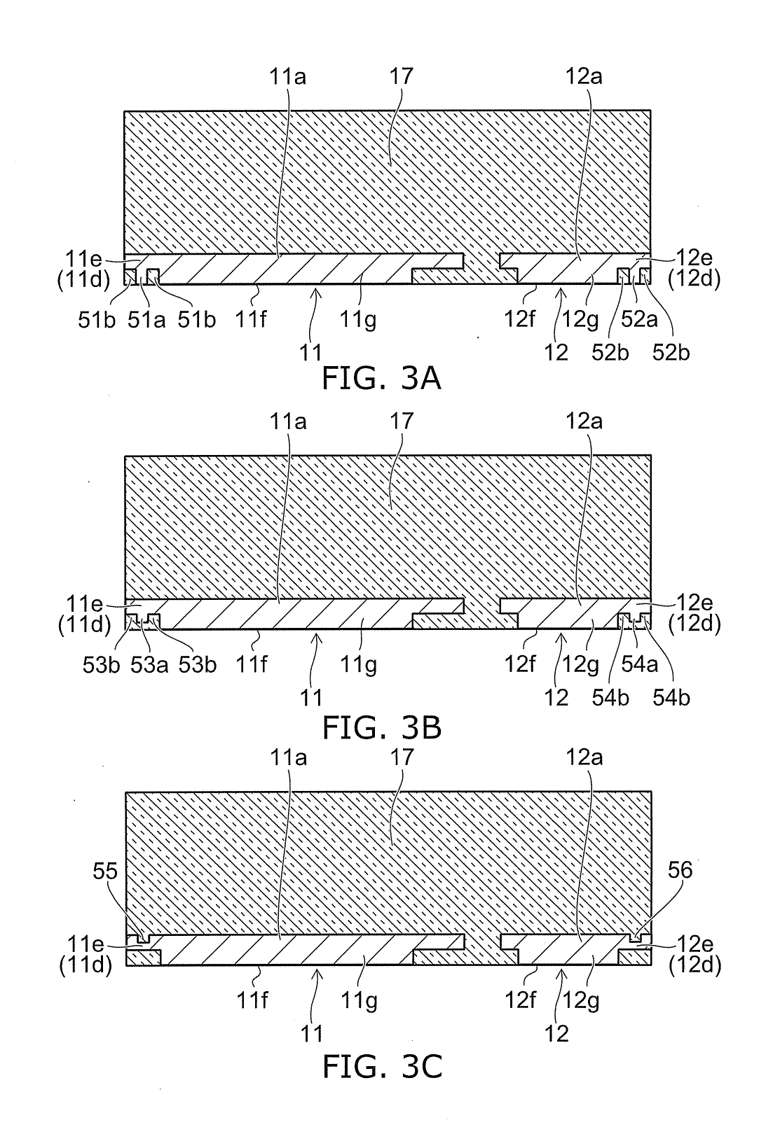

FIG. 3A is a schematic cross-sectional view illustrating only leadframes 11 and 12 and a transparent resin body 17 of FIG. 2A.

The LED package 1 includes a first leadframe (hereinbelow also called simply the leadframe) 11 and a second leadframe (hereinbelow also called simply the leadframe) 12. The leadframes 11 and 12 have flat plate configurations. The leadframes 11 and 12 are disposed on the same plane and are separated from each other in the planar direction. The leadframes 11 and 12 are made of the same conductive material and have a structure in which, for example, silver plating layers are formed on the upper surface and the lower surface of a copper plate. The silver plating layers are not formed and the copper plate is exposed at the end surfaces of the leadframes 11 and 12.

Hereinbelow, for convenience of description in the specification, an XYZ orthogonal coordinate system is introduced. A direction parallel to the upper surfaces of the leadframes 11 and 12 from the leadframe 11 toward the leadframe 12 is taken as a +X direction. An upward direction perpendicular to the upper surfaces of the leadframes 11 and 12, that is, the direction in which an LED chip 14 is mounted as viewed from the leadframes, is taken as a +Z direction. One direction orthogonal to both the +X direction and the +Z direction is taken as a +Y direction. The directions opposite to the +X direction, the +Y direction, and the +Z direction are taken as a −X direction, a −Y direction, and a −Z direction, respectively. The +X direction and the −X direction, for example, also are generally referred to as simply the X direction.

The leadframe 11 includes one base portion 11a which is rectangular as viewed from the Z direction. Four extending portions 11b, 11c, 11d, and 11e extend from the base portion 11a.

The extending portion 11b extends toward the +Y direction from the X-direction central portion of the end edge of the base portion 11a facing the +Y direction. The extending portion 11c extends toward the −Y direction from the X-direction central portion of the end edge of the base portion 11a facing the −Y direction. The positions of the extending portions 11b and 11c in the X direction are the same. The extending portions 11d and 11e extend toward the −X direction from both end portions of the end edge of the base portion 11a facing the −X direction. Thus, the extending portions 11b to 11e extend respectively from three mutually different sides of the base portion 11a.

Compared to the leadframe 11, the length of the leadframe 12 is shorter in the X direction; and the lengths in the Y direction are the same. The leadframe 12 includes one base portion 12a which is rectangular as viewed from the Z direction. Four extending portions 12b, 12c, 12d, and 12e extend from the base portion 12a.

The extending portion 12b extends toward the +Y direction from the end portion on the −X direction side of the end edge of the base portion 12a facing the +Y direction. The extending portion 12c extends toward the −Y direction from the end portion on the −X direction side of the end edge of the base portion 12a facing the −Y direction. The extending portions 12d and 12e extend toward the +X direction from both end portions of the end edge of the base portion 12a facing the +X direction. Thus, the extending portions 12b to 12e extend respectively from three mutually different sides of the base portion 12a.

The widths of the extending portions 11d and 11e of the leadframe 11 may be the same as the widths of the extending portions 12d and 12e of the leadframe 12 or may be different. It is easy to discriminate between the anode and the cathode by making the widths of the extending portions 11d and 11e different from the widths of the extending portions 12d and 12e.

A protrusion 11g is formed in the X-direction central portion of the base portion 11a of a lower surface 11f of the leadframe 11. Therefore, the thickness of the leadframe 11 has two levels of values. The X-direction central portion of the base portion 11a, i.e., the portion where the protrusion 11g is formed, is relatively thick; and both X-direction end portions of the base portion 11a and the extending portions 11b to 11e are relatively thin. However, a protrusion 51a described below provided on the extending portions 11d and 11e has the same thickness (protruding length) as the protrusion 11g of the base portion 11a. In FIGS. 2A and 2B, the portion of the base portion 11a where the protrusion 11g is not formed is illustrated as a thin plate portion lit.

A protrusion 12g is formed in the X-direction central portion of the base portion 12a of a lower surface 12f of the leadframe 12. Thereby, the thickness of the leadframe 12 also has two levels of values. The X-direction central portion of the base portion 12a is relatively thick because the protrusion 12g is formed; and both X-direction end portions of the base portion 12a and the extending portions 12b to 12e are relatively thin. However, a protrusion 52a described below provided on the extending portions 12d and 12e has the same thickness (protruding length) as the protrusion 12g of the base portion 12a. In FIGS. 2A and 2B, the portion of the base portion 12a where the protrusion 12g is not formed is illustrated as a thin plate portion 12t.

In FIG. 2B, the relatively thin portions of the leadframes 11 and 12 are illustrated by broken line hatching.

Notches extending in the Y direction are made respectively in the lower surfaces of both of the X-direction end portions of the base portions 11a and 12a along the end edges of the base portions 11a and 12a.

The protrusions 11g and 12g are formed in regions of the leadframes 11 and 12 distal to the mutually-opposing end edges. The regions of the leadframes 11 and 12 including the mutually-opposing end edges are the thin plate portions 11t and 12t.

An upper surface 11h of the leadframe 11 and an upper surface 12h of the leadframe 12 are on the same plane. The lower surface of the protrusion 11g of the leadframe 11 and the lower surface of the protrusion 12g of the leadframe 12 are on the same plane. The position of the upper surface of each of the extending portions in the Z direction matches the positions of the upper surfaces of the leadframes 11 and 12. Accordingly, each of the extending portions is disposed on the same XY plane.

An unevenness is provided in the lower surface of the extending portion 11d of the leadframe 11. For example, one protrusion 51a and two recesses 51b adjacent to the two X-direction side surfaces of the one protrusion 51a are provided in the lower surface of the extending portion 11d. The protrusion 51a protrudes toward the side opposite to the mounting surface of the LED chip 14 and has the same protruding length as the protrusion 11g of the base portion 11a. In other words, the lower surface of the protrusion 51a and the lower surface of the protrusion 11g are on the same plane. As illustrated in FIG. 2B, the protrusion 51a extends in the Y direction.

Similarly, the protrusion 51a and the recess 51b are provided also in the lower surface of the extending portion 11e. A similar unevenness may be provided also in the lower surfaces of the extending portions 11b and 11c.

An unevenness is provided also in the lower surface of the extending portion 12d of the leadframe 12. For example, one protrusion 52a and two recesses 52b adjacent to the two X-direction side surfaces of the one protrusion 52a are provided in the lower surface of the extending portion 12d. The protrusion 52a protrudes downward from the leadframe 12 and has the same protruding length as the protrusion 12g of the base portion 12a. In other words, the lower surface of the protrusion 52a and the lower surface of the protrusion 12g are on the same plane. As illustrated in FIG. 2B, the protrusion 52a extends in the Y direction.

Similarly, the protrusion 52a and the recess 52b are provided also in the lower surface of the extending portion 12e. A similar unevenness may be provided also in the lower surfaces of the extending portions 12b and 12c.

A die mount material 13 is bonded to cover a portion of the region of the upper surface 11h of the leadframe 11 corresponding to the base portion 11a. The die mount material 13 may be conductive or insulative. For example, silver paste, solder, eutectic solder, etc., may be used as the conductive die mount material 13. For example, a transparent resin paste may be used as the insulative die mount material 13.

The LED chip 14 is mounted on the die mount material 13. The LED chip 14 is affixed to the leadframe 11 by the die mount material 13. The LED chip 14 has, for example, a structure in which a semiconductor layer including a light emitting layer made of gallium nitride (GaN), etc., is stacked on a sapphire substrate. The configuration of the LED chip 14 is, for example, a rectangular parallelepiped; and terminals 14a and 14b are provided in the upper surface thereof. The LED chip 14 emits, for example, a blue light by a current being injected into the light emitting layer by a voltage being supplied between the terminal 14a and the terminal 14b.

One end of a wire 15 is bonded to the terminal 14a of the LED chip 14. The wire 15 is drawn out from the terminal 14a in the +Z direction (the upward perpendicular direction) and curves toward a direction between the −X direction and the −Z direction; and the other end of the wire 15 is bonded to the upper surface 11h of the leadframe 11. Thereby, the terminal 14a is connected to the leadframe 11 via the wire 15.

On the other hand, one end of a wire 16 is bonded to the terminal 14b. The wire 16 is drawn out from the terminal 14b in the +Z direction and curves toward a direction between the +X direction and the −Z direction; and the other end of the wire 16 is bonded to the upper surface 12h of the leadframe 12. Thereby, the terminal 14b is connected to the leadframe 12 via the wire 16. The wires 15 and 16 are formed of a metal, e.g., gold or aluminum.

The LED package 1 further includes the transparent resin body 17. The transparent resin body 17 is a resin transparent to the light emitted from the LED chip 14, e.g., a silicone resin. “Transparent” also includes being semi-transparent. The exterior form of the transparent resin body 17 is, for example, a rectangular parallelepiped.

The leadframes 11 and 12, the die mount material 13, the LED chip 14, and the wires 15 and 16 are buried in the transparent resin body 17. The transparent resin body 17 is filled into the recess 51b provided on the lower surface sides of the extending portions 11d and 11e. The transparent resin body 17 is filled also into the recess 52b provided on the lower surface sides of the extending portions 12d and 12e. In other words, the exterior form of the transparent resin body 17 is used as the exterior form of the LED package 1.

A portion of the leadframe 11 and a portion of the leadframe 12 are exposed at the lower surface and the side surface of the transparent resin body 17. In other words, the transparent resin body 17 covers the LED chip 14, covers the upper surface, a portion of the lower surface, and a portion of the end surface of the leadframe 11, and covers the upper surface, a portion of the lower surface, and a portion of the end surface of the leadframe 12. The remaining portion of the lower surface and the remaining portion of the end surface of the leadframe 11 and the remaining portion of the lower surface and the remaining portion of the end surface of the leadframe 12 are exposed from the transparent resin body 17. In the specification, the concept of covering includes both the case of the covering component being in contact with the covered component and the case of not being in contact.

The lower surface of the protrusion 11g of the base portion 11a of the leadframe 11 and the lower surface of the protrusion 51a of the extending portions 11d and 11e are exposed at the lower surface of the transparent resin body 17. The protruding-direction tip surface of each of the extending portions 11b to 11e is exposed at the side surface of the transparent resin body 17. The configuration of the transparent resin body 17 is rectangular when viewed in the top view; and the tip surfaces of the multiple extending portions 11b to 11e are exposed at three mutually different side surfaces of the transparent resin body 17.

The transparent resin body 17 covers the entire upper surface 11h of the leadframe 11, the lower surface of the thin plate portion lit, the +X direction end surface of the thin plate portion 11t, the Y-direction end surfaces of the thin plate portion 11t, the Y-direction end surfaces of the base portion 11a, the Y-direction end surfaces of the protrusion 11g, the X-direction end surfaces of the protrusion 11g, the Y-direction end surfaces of the protrusion 51a, the X-direction end surfaces of the protrusion 51a (the inner wall surfaces of the recesses 51b), the X-direction end surfaces of the extending portions 11b and 11c, and the Y-direction end surfaces of the extending portions 11d and 11e.

The lower surface of the protrusion 12g of the base portion 12a of the leadframe 12 and the lower surface of the protrusion 52a of the extending portions 12d and 12e are exposed at the lower surface of the transparent resin body 17. The protruding-direction tip surface of each of the extending portions 12b to 12e is exposed at the side surface of the transparent resin body 17. The tip surfaces of the multiple extending portions 12b to 12e are exposed at three mutually different side surfaces of the transparent resin body 17.

The transparent resin body 17 covers the entire upper surface 12h of the leadframe 12, the lower surface of the thin plate portion 12t, the −X direction end surface of the thin plate portion 12t, the Y-direction end surfaces of the base portion 12a, the Y-direction end surfaces of the protrusion 12g, the X-direction end surfaces of the protrusion 12g, the Y-direction end surfaces of the protrusion 52a, the X-direction end surfaces of the protrusion 52a (the inner wall surfaces of the recesses 52b), the X-direction end surfaces of the extending portions 12b and 12c, and the Y-direction end surfaces of the extending portions 12d and 12e.

In the LED package 1, the lower surfaces of the protrusions 11g and 12g exposed at the lower surface of the transparent resin body 17 are used as external electrode pads.

Many phosphors 18 are dispersed in the interior of the transparent resin body 17. Each of the phosphors 18 has a granular configuration and is configured to absorb the light emitted from the LED chip 14 and emit light of a longer wavelength. The transparent resin body 17 is transmissive also with respect to the light emitted by the phosphor 18.

For example, the phosphor 18 absorbs a portion of the blue light emitted from the LED chip 14 and emits yellow light. Thereby, the LED package 1 emits the blue light emitted by the LED chip 14 and not absorbed into the phosphor 18 and the yellow light emitted from the phosphor 18; and the emitted light as an entirety is white.

A silicate-based phosphor that emits yellowish-green, yellow, or orange light, for example, can be used as the phosphor 18. The silicate-based phosphor can be represented by the following general formula.

(2-x-y)SrO.x(Baᵤ,Caᵥ)O.(1-a-b-c-d)SiO₂.aP₂O₅bAl₂O₃cB₂O₃dGeO₂:yEu²⁺

where 0<x, 0.005<y<0.5, x+y≦1.6, 0≦a, b, c, d<0.5, 0<u, 0<v, and u+v=1.

A YAG-based phosphor also can be used as the yellow phosphor. The YAG-based phosphor can be represented by the following general formula.

(RE₁₋ₓSmₓ)₃(Al_{y}Ga_{1-y})₅O₁₂:Ce

where 0.5≦x<1, 0≦y≦1, and RE is at least one type of element selected from Y and Gd.

Or, a SiAlON-based red phosphor and green phosphor can be mixed and used as the phosphor 18. In other words, the phosphor 18 may be a green phosphor that absorbs the blue light emitted from the LED chip 14 to emit green light and a red phosphor that absorbs the blue light to emit red light.

The SiAlON-based red phosphor can be represented by, for example, the general formula recited below.

(M₁₋ₓRₓ)ₐ₁AlSi_{b1}O_{c1}N_{d1}

where M is at least one type of metal element excluding Si and Al, and it may be used for M to be at least one selected from Ca and Sr; R is a light emission center element, and it may be used for R to be Eu; and x, a1, b1, c1, and d1 satisfy the relationships 0<x≦1, 0.6<a1<0.95, 2<b1<3.9, 0.25<c1<0.45, and 4<d1<5.7.

A specific example of such a SiAlON-based red phosphor is as follows.

Sr₂Si₇Al₇ON₁₃:Eu²⁺

The SiAlON-based green phosphor can be represented by, for example, the general formula recited below.

(M₁₋ₓRₓ)ₐ₂AlSi_{b2}O_{c2}N_{d2}

where M is at least one type of metal element excluding Si and Al, and it may be used for M to be at least one selected from Ca and Sr; R is a light emission center element, and it may be used for R to be Eu; and x, a2, b2, c2, and d2 satisfy the relationships 0<x≦1, 0.93<a2<1.3, 4.0<b2<5.8, 0.6<c2<1, and 6<d2<11.

A specific example of such a SiAlON-based green phosphor is as follows.

Sr₃Si₁₃Al₃O₂N₂₁:Eu²⁺

A method for manufacturing the LED package of the embodiment will now be described.

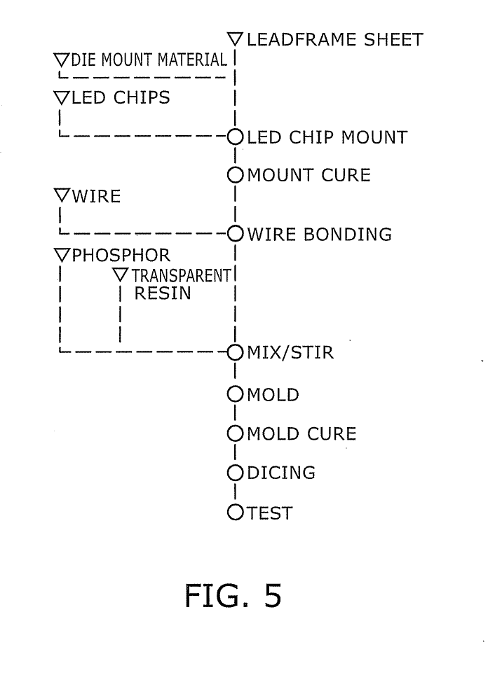

FIG. 5 is a flowchart illustrating the method for manufacturing the LED package of the embodiment.

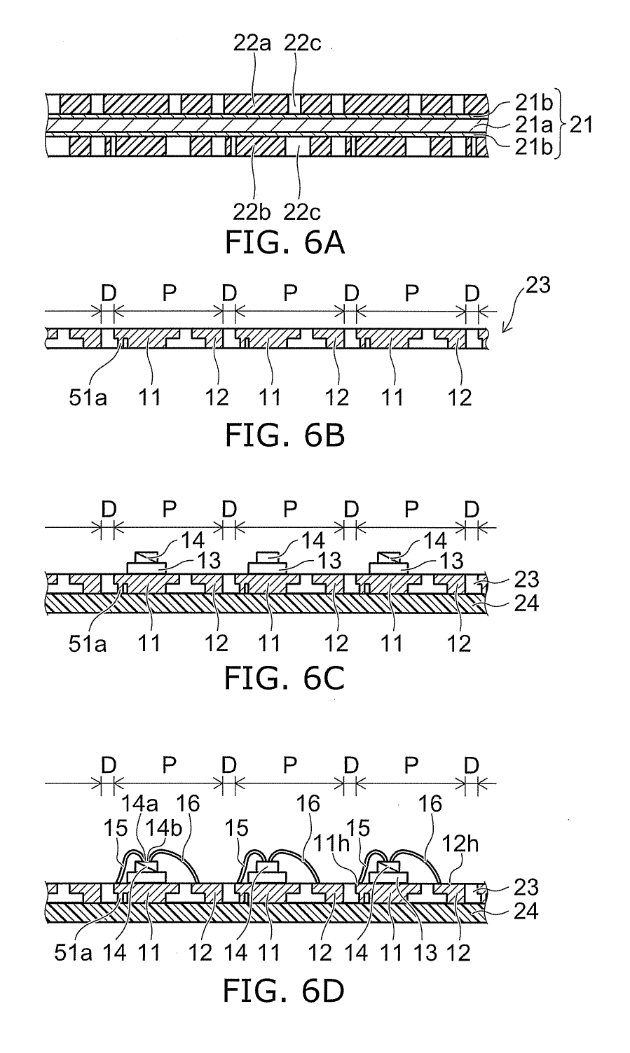

FIG. 6A to FIG. 8B are cross-sectional views of processes, illustrating the method for manufacturing the LED package of the embodiment.

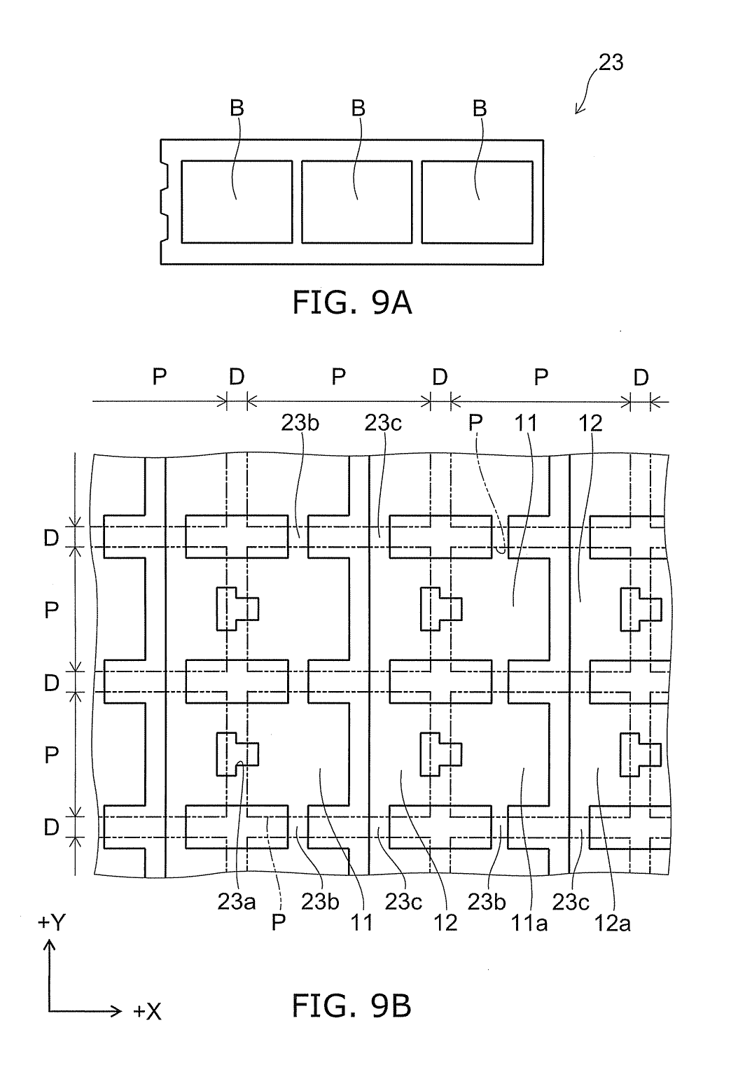

FIG. 9A is a plan view illustrating a leadframe sheet of the embodiment; and FIG. 9B is a partially-enlarged plan view illustrating device regions of the leadframe sheet.

First, as illustrated in FIG. 6A, a conductive sheet 21 made of a conductive material is prepared. The conductive sheet 21 includes, for example, silver plating layers 21b plated on the upper surface and the lower surface of a copper plate 21a having a rectangular configuration.

Then, a mask 22a is formed on one surface (the upper surface in the drawings) of the conductive sheet 21; and a mask 22b is formed on another surface (the lower surface in the drawings). Openings 22c are made selectively in the masks 22a and 22b. The masks 22a and 22b may be formed using, for example, printing.

Then, wet etching is performed on the conductive sheet 21 by immersing the conductive sheet 21 over which the masks 22a and 22b are bonded in an etchant. Thereby, the portions of the conductive sheet 21 positioned inside the openings 22c are selectively removed by etching.

At this time, the etching amount is controlled by adjusting, for example, the immersion time; and the etching is stopped before the etching from the upper surface side of the conductive sheet 21 or the etching from the lower surface side of the conductive sheet 21 independently pierces the conductive sheet 21. Thereby, half-etching is performed from the upper surface side and the lower surface side. However, portions etched from both the upper surface side and the lower surface side pierce the conductive sheet 21. Subsequently, the masks 22a and 22b are removed.

Thereby, as illustrated in FIG. 6B, the copper plate 21a and the silver plating layers 21b are selectively removed from the conductive sheet 21 to form a leadframe sheet 23. For convenience of illustration in FIG. 6B and subsequent drawings, the copper plate 21a and the silver plating layers 21b are illustrated integrally as the leadframe sheet 23 without being discriminated. The selective etching recited above also forms the unevenness described above in the lower surface side of the extending portions. FIGS. 6B to 6D illustrate, for example, the protrusion 51a provided on the extending portions 11d and 11e of the leadframe 11.

In the leadframe sheet 23 as illustrated in FIG. 9A, for example, three blocks B are set; and, for example, about 1000 device regions P are set in each of the blocks B. As illustrated in FIG. 9B, the device regions P are arranged in a matrix configuration; and the region between the device regions P is used as a dicing region D having a lattice configuration. A basic pattern including mutually-separated leadframes 11 and 12 is formed in each of the device regions P. In the dicing region D, the conductive material of the conductive sheet 21 remains to link mutually-adjacent device regions P.

In other words, although the leadframe 11 and the leadframe 12 are mutually separated in the device region P, the leadframe 11 belonging to one of the device regions P is linked to the leadframe 12 belonging to the adjacent device region P positioned in the −X direction as viewed from the one of the device regions P; and an opening 23a having a protruding configuration facing the +X direction is made between the two frames.

The leadframes 11 belonging to the device regions P adjacent to each other in the Y direction are linked to each other via a bridge 23b. Similarly, the leadframes 12 belonging to the device regions P adjacent to each other in the Y direction are linked to each other via a bridge 23c. Thereby, four conductive members extend toward three directions from the base portions 11a and 12a of the leadframes 11 and 12. The protrusions 11g, 51a, 12g, and 52a (referring to FIG. 3A) are formed on the lower surfaces of the leadframes 11 and 12 respectively by the etching from the lower surface side of the leadframe sheet 23 being half-etching.

Then, as illustrated in FIG. 6C, a reinforcing tape 24 made of, for example, polyimide is adhered to the lower surface of the leadframe sheet 23. Continuing, the die mount material 13 is bonded to cover the leadframe 11 belonging to each of the device regions P of the leadframe sheet 23. For example, the die mount material 13 having a paste configuration may be dispensed onto the leadframe 11 from a dispenser or transferred onto the leadframe 11 using mechanical means.

Then, the LED chip 14 is mounted on the die mount material 13. Then, heat treatment (mount cure) is performed to cure the die mount material 13. Thereby, the LED chip 14 is mounted via the die mount material 13 on the leadframe 11 of each of the device regions P of the leadframe sheet 23.

Continuing as illustrated in FIG. 6D, one end of the wire 15 is bonded to the terminal 14a of the LED chip 14 and the other end is bonded to the upper surface of the leadframe 11 using, for example, ultrasonic bonding. One end of the wire 16 is bonded to the terminal 14b of the LED chip 14; and the other end is bonded to the upper surface 12h of the leadframe 12. Thereby, the terminal 14a is connected to the leadframe 11 via the wire 15; and the terminal 14b is connected to the leadframe 12 via the wire 16.

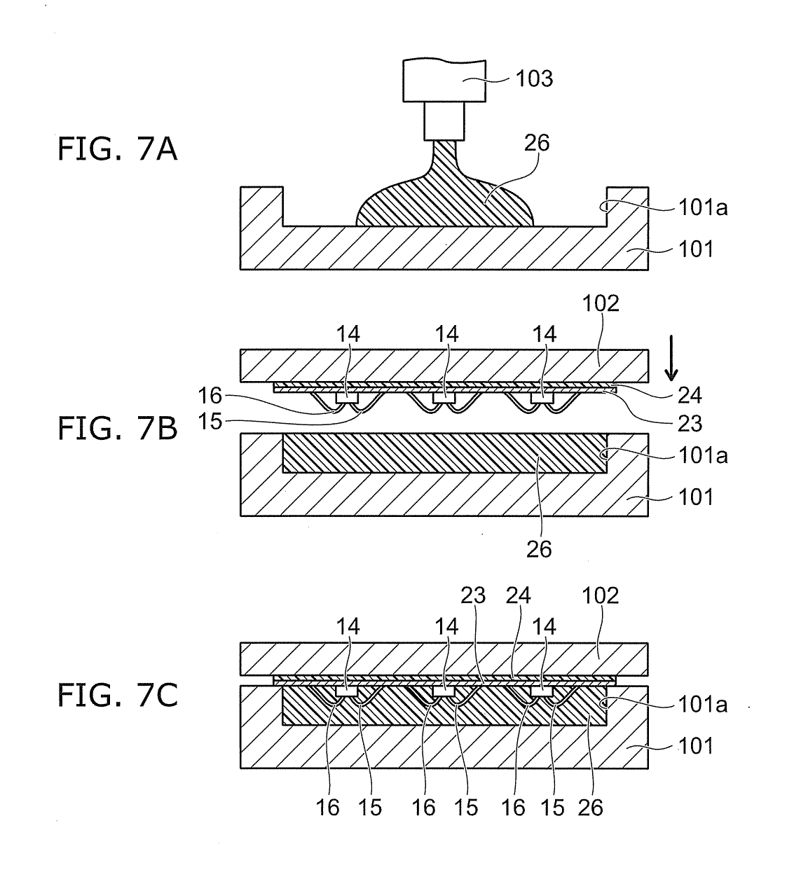

Then, as illustrated in FIG. 7A, a lower die 101 is prepared. The lower die 101 is included in one die set with an upper die 102 described below; and a recess 101a having a rectangular parallelepiped configuration is made in the upper surface of the lower die 101. On the other hand, a liquid or semi-liquid phosphor-containing resin material 26 is prepared by mixing the phosphor 18 (referring to FIG. 2A) into a transparent resin such as a silicone resin and stirring. Then, the phosphor-containing resin material 26 is supplied to the recess 101a of the lower die 101 using a dispenser 103.

Continuing as illustrated in FIG. 7B, the leadframe sheet 23 on which the LED chips 14 described above are mounted is mounted to the lower surface of the upper die 102 such that the LED chips 14 face downward. Then, the die is closed by pressing the upper die 102 onto the lower die 101. Thereby, the leadframe sheet 23 is pressed onto the phosphor-containing resin material 26. At this time, the phosphor-containing resin material 26 covers the LED chips 14 and the wires 15 and 16 and enters also into the portion of the leadframe sheet 23 removed by the etching. Thus, the phosphor-containing resin material 26 is molded.

Then, as illustrated in FIG. 7C, heat treatment (mold cure) is performed in a state in which the upper surface of the leadframe sheet 23 is pressed onto the phosphor-containing resin material 26 to cure the phosphor-containing resin material 26.

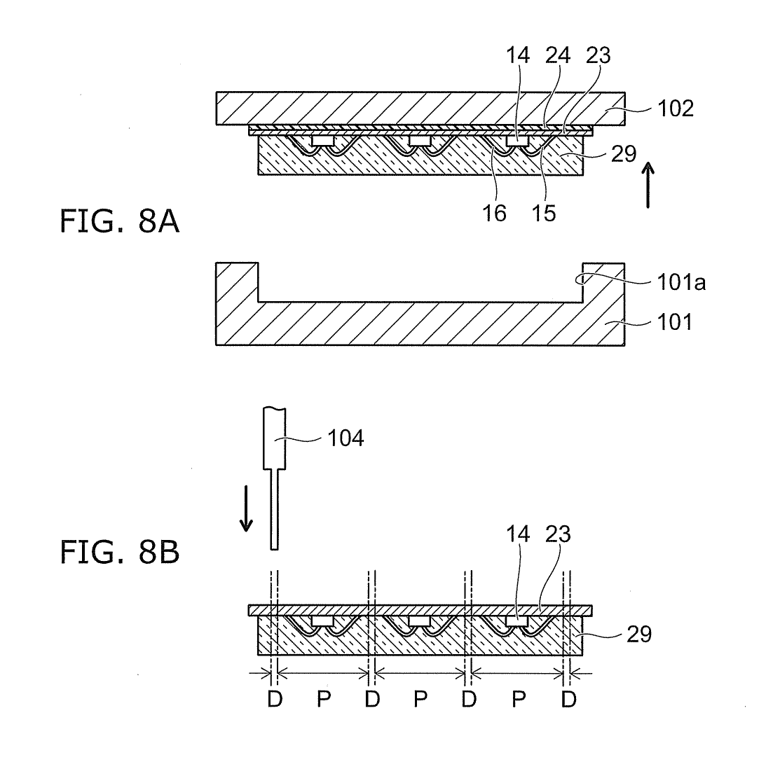

Subsequently, as illustrated in FIG. 8A, the upper die 102 is pulled away from the lower die 101. Thereby, a transparent resin plate 29 is formed on the leadframe sheet 23 to cover the entire upper surface and a portion of the lower surface of the leadframe sheet 23 to bury the LED chips 14, etc. The phosphor 18 (referring to FIG. 2A) is dispersed in the transparent resin plate 29. Subsequently, the reinforcing tape 24 is peeled from the leadframe sheet 23. Thereby, the lower surfaces of the protrusions 11g and 51a of the leadframe 11 and the protrusions 12g and 52a of the leadframe 12 (referring to FIG. 2A and FIG. 3A) are exposed at the surface of the transparent resin plate 29.

Then, as illustrated in FIG. 8B, dicing is performed on the bonded body made of the leadframe sheet 23 and the transparent resin plate 29 from the leadframe sheet 23 side using a blade 104. In other words, dicing is performed from the −Z direction side toward the +Z direction. Thereby, the portions of the leadframe sheet 23 and the transparent resin plate 29 disposed in the dicing region D are removed.

As a result, the portions of the leadframe sheet 23 and the transparent resin plate 29 disposed in the device regions P are singulated; and the LED package 1 illustrated in FIG. 1 and FIGS. 2A and 2B is manufactured. The bonded body made of the leadframe sheet 23 and the transparent resin plate 29 may be diced from the transparent resin body 29 side.

The leadframes 11 and 12 are separated from the leadframe sheet 23 in each of the LED packages 1 after the dicing. The transparent resin plate 29 is divided to form the transparent resin body 17. The extending portions 11d, 11e, 12d, and 12e are formed in the leadframes 11 and 12 respectively by the portion of the dicing region D that extends in the Y direction passing through the openings 23a of the leadframe sheet 23. The extending portions 11b and 11c are formed in the leadframe 11 by the bridge 23b being divided; and the extending portions 12b and 12c are formed in the leadframe 12 by the bridge 23c being divided. The tip surfaces of the extending portions 11b to 11e and 12b to 12e are exposed at the side surface of the transparent resin body 17.

Then, as illustrated in FIG. 5, various tests are performed on the LED package 1. At this time, it is also possible to use the tip surfaces of the extending portions 11b to 11e and 12b to 12e as the terminals for the tests.

Because a casing made of a white resin is not provided in the LED package 1 according to the embodiment, the casing does not degrade by absorbing the light and the heat generated by the LED chip 14. Although the degradation progresses easily particularly in the case where the casing is formed of a polyamide-based thermoplastic resin, there is no such risk in the embodiment. Therefore, the LED package 1 according to the embodiment has high durability. Accordingly, the LED package 1 according to the embodiment has a long life, high reliability, and is applicable to a wide range of applications.

In the LED package 1 according to the embodiment, the transparent resin body 17 is formed of a silicone resin. The durability of the LED package 1 also improves because the silicone resin has high durability to the light and the heat.

In the LED package 1 according to the embodiment, the light is emitted toward a wide angle because a casing covering the side surface of the transparent resin body 17 is not provided. Therefore, the LED package 1 according to the embodiment is advantageous when used in applications in which it is necessary for the light to be emitted at a wide angle, e.g., the backlight of a liquid crystal display apparatus and illumination.

In the LED package 1 according to the embodiment, the transparent resin body 17 maintains the peripheral portions of the leadframes 11 and 12 by covering a portion of the lower surfaces and the greater part of the end surfaces of the leadframes 11 and 12. Therefore, the maintenance of the leadframes 11 and 12 can be better while realizing the external electrode pads by exposing the lower surfaces of the protrusions 11g and 12g of the leadframes 11 and 12 from the transparent resin body 17.

In other words, notches are realized at both X-direction end portions of the lower surfaces of the base portions 11a and 12a by forming the protrusions 11g and 12g in the X-direction central portions of the base portions 11a and 12a. The leadframes 11 and 12 can be securely maintained by the transparent resin body 17 extending around inside the notches. Thereby, the leadframes 11 and 12 do not easily peel from the transparent resin body 17 during the dicing; and the yield of the LED package 1 can be increased.

Further, in the LED package 1 according to the embodiment, the silver plating layers are formed on the upper surfaces and the lower surfaces of the leadframes 11 and 12. The light extraction efficiency of the LED package 1 according to the embodiment is high because the silver plating layers have high optical reflectance of the light.

In the embodiment, many, e.g., about several thousand, of the LED packages 1 can be collectively manufactured from one conductive sheet 21. Thereby, the manufacturing cost per LED package 1 can be reduced. The number of parts, the number of processes, and the costs are low because the casing is not provided.

Furthermore, in the embodiment, the leadframe sheet 23 is formed using wet etching. Therefore, it is sufficient to prepare only the form of the mask when manufacturing the LED package with a new layout; and the initial cost can be kept lower than the case where the leadframe sheet 23 is formed using a method such as stamping with a die, etc.

In the LED package 1 according to the embodiment, the extending portions extend from the base portions 11a and 12a of the leadframes 11 and 12. Thereby, the base portions themselves are prevented from being exposed at the side surface of the transparent resin body 17; and the exposed surface area of the leadframes 11 and 12 can be reduced. As a result, the leadframes 11 and 12 can be prevented from peeling from the transparent resin body 17. Corrosion of the leadframes 11 and 12 also can be suppressed.

Considering these effects from the aspect of the manufacturing method, the metal portions interposed in the dicing region D are reduced by providing the opening 23a and the bridges 23b and 23c to be interposed in the dicing region D of the leadframe sheet 23 as illustrated in FIG. 9B. Thereby, the dicing is easier; and wear of the dicing blade can be suppressed.

Also, in the embodiment, four extending portions extend in three directions from each of the leadframes 11 and 12. Thereby, the mountability is high because the leadframe 11 is reliably supported from the three directions by the leadframes 11 and 12 of the adjacent device regions P in the mount process of the LED chip 14 illustrated in FIG. 6C. Similarly, in the wire bonding process illustrated in FIG. 6D, for example, there is not much loss of the ultrasonic waves applied during the ultrasonic bonding and good bonding of the wires to the leadframes and the LED chip can be provided because the bonding positions of the wires are reliably supported from the three directions.

In the embodiment, the dicing is performed from the leadframe sheet 23 side in the dicing process illustrated in FIG. 8B. Thereby, the metal material of the cutting end portions of the leadframes 11 and 12 elongates over the side surface of the transparent resin body 17 in the +Z direction. Therefore, this metal material does not elongate over the side surface of the transparent resin body 17 in the −Z direction to protrude from the lower surface of the LED package 1; and burrs do not occur. Accordingly, mounting defects due to burrs do not occur when mounting the LED package 1.

In the embodiment as described above, the peeling between the leadframes 11 and 12 and the transparent resin body 17 is suppressed by reducing the exposed surface area of the leadframes 11 and 12 by limiting the portions of the leadframes 11 and 12 exposed at the side surface of the transparent resin body 17 to the tip surfaces of the extending portions. Accordingly, the risk of peeling between the leadframes 11 and 12 and the transparent resin body 17 exists at the portions of the extending portions.

Therefore, in the embodiment as illustrated in FIG. 1, FIG. 2A, FIG. 2B, and FIG. 3A, for example, the protrusion 51a and the recess 51b are provided in the lower surfaces of the extending portions 11e and 11d; and the protrusion 52a and the recess 52b are provided in the lower surfaces of the extending portions 12e and 12d. The peeling between the leadframes 11 and 12 and the transparent resin body 17 can be suppressed by increasing the adhesion strength between the extending portions and the transparent resin body 17 by providing the unevenness in the extending portions.

The increase of the adhesion strength between the leadframes 11 and 12 and the transparent resin body 17 suppresses air entering the gaps between the leadframes 11 and 12 and the transparent resin body 17; and degradation of the light emission characteristics, the life, etc., is suppressed.

Even in the case where the transparent resin body 17 peels inside the recess 51b and 52b further to the outside than the protrusions 51a and 52a, the protrusions 51a and 52a act as barriers and can prevent the peeling from progressing inward. In other words, the protrusions 51a and 52a function as baffles configured to partition the portions of the transparent resin body 17 on the side surface side from the portions further inward and can prevent the transparent resin body 17 from peeling from the leadframes 11 and 12 continuously from the outside inward.

Unlike stamping, the unevenness of the extending portions does not cause a mechanical load on the leadframes because the leadframe sheet 23 is formed using wet etching as described above. Thereby, damage, configurational degradation, and dimensional fluctuation of the leadframes can be suppressed.

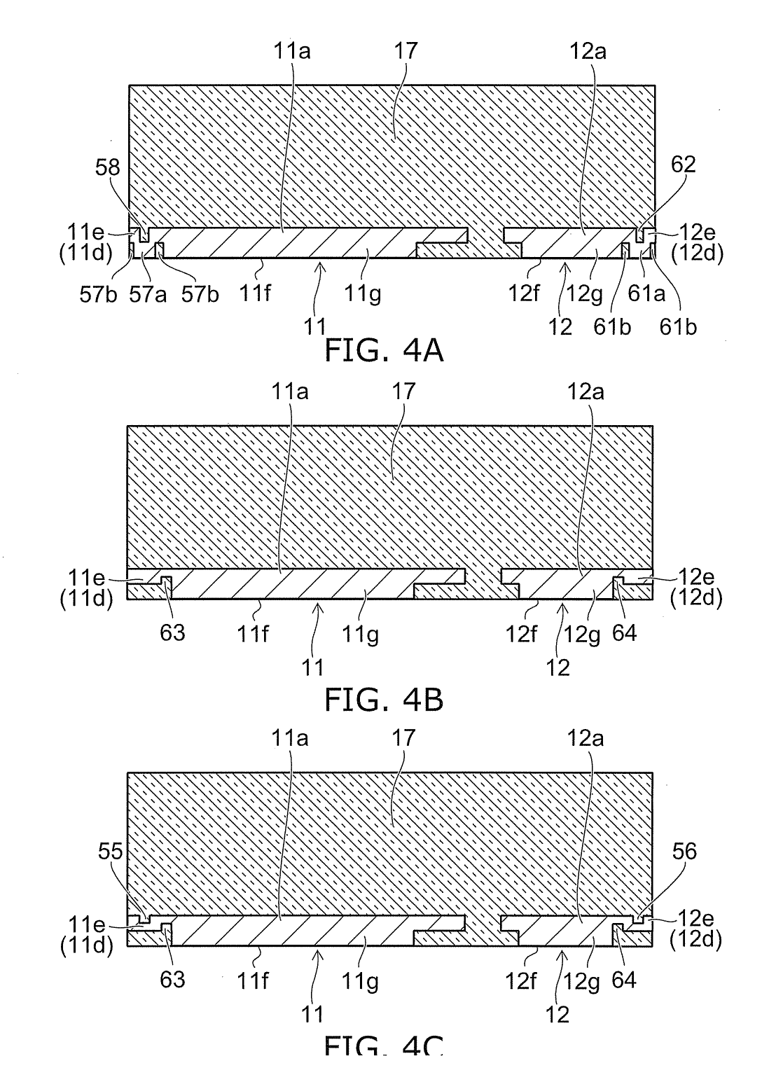

Other specific examples in which an unevenness is provided in the extending portions will now be described with reference to FIG. 3B to FIG. 4C. FIG. 3B to FIG. 4C correspond to the same cross section as FIG. 3A.

In the specific examples illustrated in FIG. 3B to FIG. 4C as well, the peeling between the leadframes 11 and 12 and the transparent resin body 17 can be suppressed by increasing the adhesion strength between the extending portions and the transparent resin body 17 by providing an unevenness in the extending portions. As a result, air entering the gaps between the leadframes 11 and 12 and the transparent resin body 17 is suppressed; and the degradation of the light emission characteristics, the life, etc., can be suppressed.

In the specific example of FIG. 3B, similarly to the specific example of FIG. 3A, a protrusion 53a and a recess 53b are provided in the lower surfaces of the extending portions 11e and 11d; and a protrusion 54a and a recess 54b are provided in the lower surfaces of the extending portions 12e and 12d. However, the protruding lengths of the protrusions 53a and 54a are shorter than those of the protrusions 11g and 12g provided under the base portions 11a and 12a. In other words, the lower surface of the protrusion 53a and the lower surface of the protrusion 54a are covered with the transparent resin body 17.

Therefore, in the process illustrated in FIG. 7C described above, it is easy to fill the resin inward of the protrusion or into the inner portion of the recess when pressing the leadframe sheet 23 onto the phosphor-containing resin material 26. As a result, the reliability can be increased by eliminating unfilled locations of the transparent resin body 17.

In the specific example of FIG. 3C, a recess 55 is provided in the upper surfaces of the extending portions 11e and 11d; and a recess 56 is provided in the upper surfaces of the extending portions 12e and 12d. The recesses 55 and 56 extend, for example, in the Y direction of FIG. 1.

The upper surfaces of the extending portions 11e and 11d are on the same plane as the upper surface of the base portion 11a; and the recess 55 is sunken with respect to the upper surfaces of the extending portions 11e and 11d. In other words, the upper surfaces of the extending portions 11e and 11d around the recess 55 are on the same plane as the upper surface of the base portion 11a.

Similarly, the upper surfaces of the extending portions 12e and 12d are on the same plane as the upper surface of the base portion 12a; and the recess 56 is sunken with respect to the upper surfaces of the extending portions 12e and 12d. In other words, the upper surfaces of the extending portions 12e and 12d around the recess 56 are on the same plane as the upper surface of the base portion 12a.

The peeling of the transparent resin body 17 of particularly the upper surface side of the extending portions can be prevented by providing the recesses 55 and 56 in the upper surfaces of the extending portions. The lower surfaces of the leadframes 11 and 12 are the mounting surfaces; and the upper surface side of the leadframes 11 and 12 functions as a light emitting unit configured to emit light to the outside. Accordingly, the prevention of the peeling of the transparent resin body 17 at the upper surface side of the leadframes 11 and 12 by providing the recesses 55 and 56 in the upper surfaces of the extending portions is effective to suppress degradation and/or fluctuation of the light emission characteristics.

A protrusion may be provided on the upper surfaces of the extending portions 11e, 11d, 12e, and 12d to protrude from the upper surfaces thereof. However, a structure in which the protrusion is provided on the upper surfaces of the extending portions which are on the same plane as the upper surfaces of the base portions 11a and 12a has many portions etched during the wet etching illustrated in FIGS. 6A and 6B compared to a structure in which the recesses 55 and 56 are provided. Accordingly, from the aspect of the manufacturing efficiency and the cost, there are cases where it is desirable to provide the recesses in the upper surfaces of the extending portions.

As illustrated in FIG. 4A, the adhesion strength between the extending portions and the transparent resin body 17 can be increased further by providing an unevenness in the upper surfaces of the extending portions and the lower surfaces.

In FIG. 4A, a protrusion 57a and a recess 57b are provided in the lower surfaces of the extending portions 11e and 11d. A recess 58 is provided in the upper surfaces of the extending portions 11e and 11d. The upper surfaces of the extending portions 11e and 11d around the recess 58 are on the same plane as the upper surface of the base portion 11a.

The protrusion 57a is provided under the recess 58; and a recess is not provided above the recess 57b. Thereby, reduced strength due to a portion of the extending portions 11e and 11d being thin can be prevented.

A protrusion 61a and a recess 61b are provided in the lower surfaces of the extending portions 12e and 12d. A recess 62 is provided in the upper surfaces of the extending portions 12e and 12d. The upper surfaces of the extending portions 12e and 12d around the recess 62 are on the same plane as the upper surface of the base portion 12a.

The protrusion 61a is provided under the recess 62; and a recess is not provided above the recess 61b. Thereby, the reduced strength due to a portion of the extending portions 12e and 12d being thin can be prevented.

FIG. 4B illustrates a specific example in which a recess 63 is provided in the lower surfaces of the extending portions 11e and 11d and a recess 64 is provided in the lower surfaces of the extending portions 12e and 12d.

A protrusion is not provided in the lower surfaces of the extending portions 11e, 11d, 12e, and 12d. Accordingly, it is easy to fill the resin into the recesses 63 and 64 when pressing the leadframe sheet 23 onto the phosphor-containing resin material 26 in the process illustrated in FIG. 7C.

FIG. 4C illustrates a structure in which the specific example of FIG. 3C is combined with the specific example of FIG. 4B.

In other words, the recess 55 is provided in the upper surfaces of the extending portions 11e and lid; and the recess 63 is provided in the lower surfaces. The reduced strength due to a portion of the extending portions 11e and 11d being thin can be prevented by shifting the planar-direction positions of the recess 55 and the recess 63.

The recess 56 is provided in the upper surfaces of the extending portions 12e and 12d; and the recess 64 is provided in the lower surfaces. The reduced strength due to a portion of the extending portions 12e and 12d being thin can be prevented by shifting the planar-direction positions of the recess 56 and the recess 64.

Providing the unevenness in the surface of the extending portion also includes providing a fine unevenness by roughening the surface of the extending portion. In such a case as well, the adhesion strength between the extending portions and the transparent resin body 17 can be increased by a so-called anchor effect.

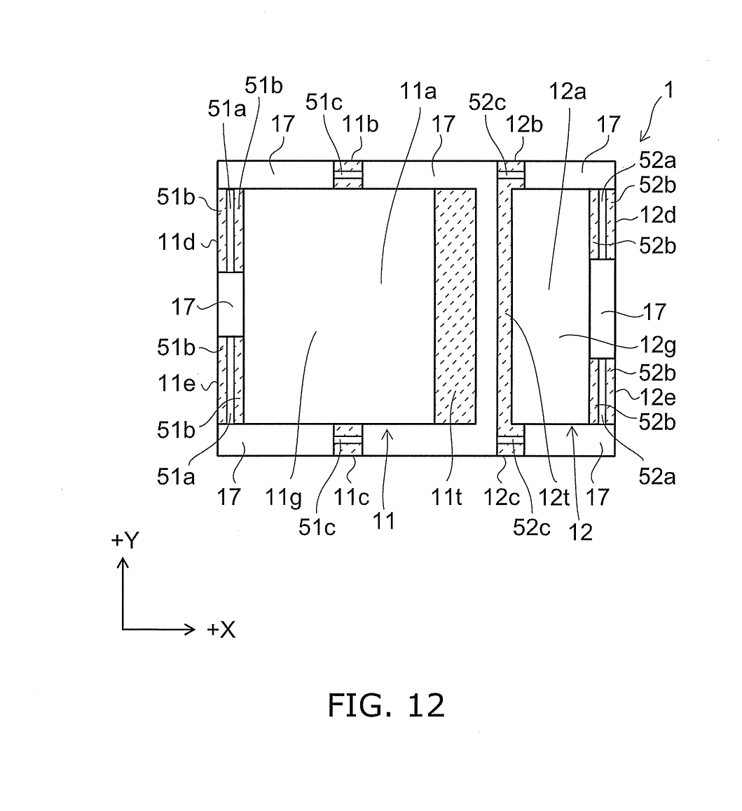

Although the unevenness is provided in the extending portions 11d, 11e, 12d, and 12e in the embodiment described above, the unevenness may be provided in the other extending portions 11b, 11c, 12b, and 12c. For example, FIG. 12 illustrates a specific example in which a protrusion 51c is provided in the lower surfaces of the extending portions 11b and 11c, and a protrusion 52c is provided on the lower surfaces of the extending portions 12b and 12c. Of course, the unevenness illustrated in FIG. 3B to FIG. 4C described above may be provided in each of the extending portions 11b, 11c, 12b, and 12c.

For example, the unevenness may be provided only in extending portions at opposite-corner positions when viewed in plan. Alternatively, the unevenness may be provided only in extending portions that extend in mutually opposite directions. Or, the unevenness may be provided only in one of the extending portions.

In any case, by providing the unevenness in at least one of the extending portions, that portion does not easily become the starting point of the peeling of the transparent resin body. As a result, an LED package having high reliability can be provided. The reliability can be increased as the number of extending portions having an unevenness increases.

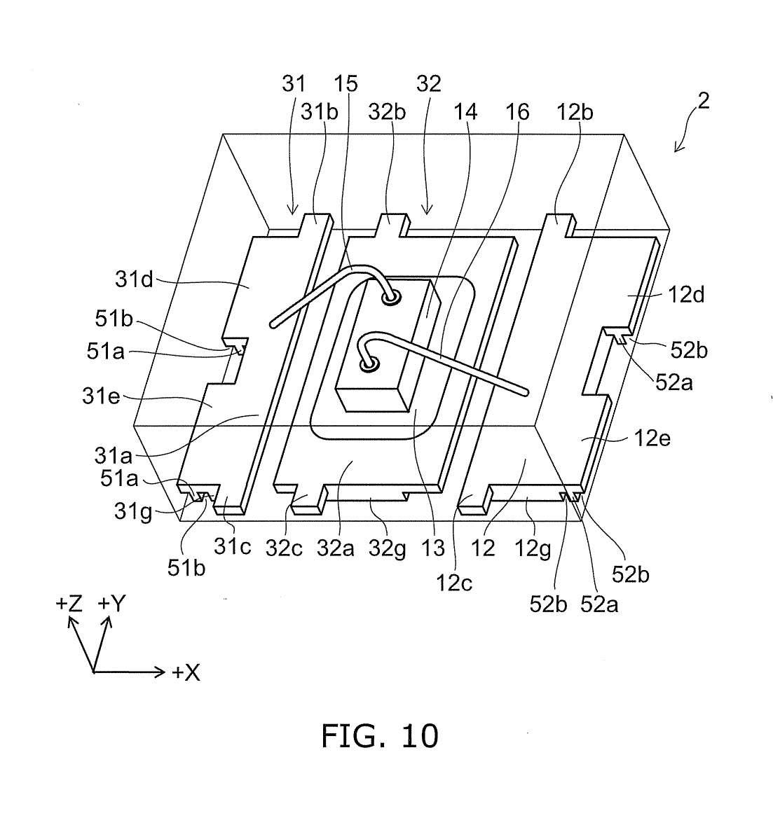

FIG. 10 is a perspective view illustrating an LED package 2 according to another embodiment.

The LED package 2 of the embodiment differs from the LED package 1 of the embodiment described above (referring to FIG. 1 and FIGS. 2A and 2B) in that the leadframe 11 is subdivided into two leadframes 31 and 32 in the X direction.

The leadframe 32 is disposed between the leadframe 31 and the leadframe 12. In the leadframe 31, extending portions 31d and 31e corresponding to the extending portions 11d and 11e of the leadframe 11 are formed; and extending portions 31b and 31c extending from a base portion 31a in the +Y direction and the −Y direction respectively are formed. The X-direction positions of the extending portions 31b and 31c are the same. The wire 15 is bonded to the leadframe 31.

On the other hand, in the leadframe 32, extending portions 32b and 32c corresponding to the extending portions 11b and 11c of the leadframe 11 are formed; and the LED chip 14 is mounted via the die mount material 13. Protrusions corresponding to the protrusion 11g of the leadframe 11 are formed as protrusions 31g and 32g by being subdivided into the leadframes 31 and 32.

In the embodiment, the leadframes 31 and 12 function as external electrodes by potentials being applied from the outside. On the other hand, it is unnecessary to apply a potential to the leadframe 32; and the leadframe 32 can be used as a dedicated heat sink leadframe. Thereby, the leadframe 32 can be connected to a common heat sink in the case where multiple LED packages 2 are mounted to one module. The grounding potential may be applied to the leadframe 32; and the leadframe 32 may be in a floating state.

A so-called Manhattan phenomenon can be suppressed by bonding solder balls respectively to the leadframes 31, 32, and 12 when mounting the LED package 2 to a motherboard. The Manhattan phenomenon refers to a phenomenon in which the device undesirably becomes upright due to a shift in the timing of the melting of the solder balls and due to the surface tension of the solder in the reflow oven when mounting the device to the substrate via multiple solder balls, etc.; and this phenomenon causes mounting defects. According to the embodiment, the Manhattan phenomenon does not occur easily because the layout of the leadframes is symmetric in the X direction and the solder balls are disposed densely in the X direction.

In the embodiment, the bondability of the wire 15 is good because the leadframe 31 is supported from three directions by the extending portions 31b to 31e. Similarly, the bondability of the wire 16 is good because the leadframe 12 is supported from three directions by the extending portions 12b to 12e.

Such an LED package 2 can be manufactured by a method similar to that of the embodiment described above by modifying the basic pattern of each of the device regions P of the leadframe sheet 23 in the process illustrated in FIG. 6A described above.

In other words, LED packages of various layouts can be manufactured by merely modifying the patterns of the masks 22a and 22b. Otherwise, the configuration, the manufacturing method, and the operational effects of the embodiment are similar to those of the embodiment described above.

In the embodiment as well, an unevenness is provided in the extending portions. Thereby, the peeling between the leadframes 31 and 12 and the transparent resin body 17 can be suppressed by increasing the adhesion strength between the extending portions and the transparent resin body 17.

Although FIG. 10 illustrates a structure in which the protrusion 51a and the recess 51b are provided in the lower surfaces of the extending portions 31d and 31e and the protrusion 52a and the recess 52b are provided in the lower surfaces of the extending portions 12d and 12e similarly to FIG. 1, this is not limited thereto. The unevenness illustrated in FIG. 3B to FIG. 4C may be provided. Also, an unevenness may be provided in the extending portions 32b and 32c of the leadframe 32.

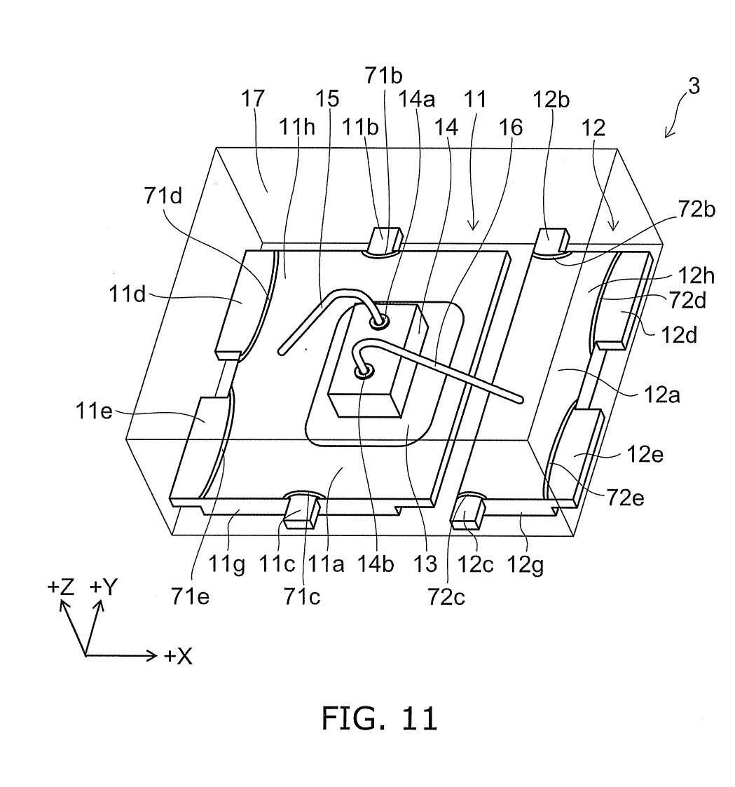

FIG. 11 is a perspective view illustrating an LED package 3 according to yet another embodiment.

The LED package 3 of the embodiment differs from the LED package 1 illustrated in FIG. 1 in that trenches are made in the upper surfaces of the leadframes 11 and 12. Although not illustrated in FIG. 11, the unevenness described above may be provided in the extending portions.

In the embodiment, the upper surfaces of the extending portions 11b to 11e and 12b to 12e and the upper surfaces of the base portions 11a and 12a are on the same plane; and the trenches are provided between the upper surfaces of the extending portions and the upper surfaces of the base portions.

Specifically, a trench 71b is made between the upper surface of the extending portion 11b and the upper surface of the base portion 11a. A trench 71c is made between the upper surface of the extending portion 11c and the upper surface of the base portion 11a. A trench 71d is made between the upper surface of the extending portion 11d and the upper surface of the base portion 11a. A trench 71e is made between the upper surface of the extending portion 11e and the upper surface of the base portion 11a.

Similarly, a trench 72b is made between the upper surface of the extending portion 12b and the upper surface of the base portion 12a. A trench 72c is made between the upper surface of the extending portion 12c and the upper surface of the base portion 12a. A trench 72d is made between the upper surface of the extending portion 12d and the upper surface of the base portion 12a. A trench 72e is made between the upper surface of the extending portion 12e and the upper surface of the base portion 12a.

The transparent resin body 17 is filled by entering each of the trenches 71b to 71e and 72b to 72e and by being cured. Thereby, the peeling between the leadframes 11 and 12 and the transparent resin body 17 can be suppressed by increasing the adhesion strength between the leadframes 11 and 12 and the transparent resin body 17.

The adhesion strength between the leadframes and the transparent resin body increases even in the case where a trench is provided between at least one of the extending portions and the base portion.

The adhesion strength between the leadframes and the transparent resin body can be increased further and the reliability can be increased further by combining the embodiment in which the trench is provided and the embodiment described above in which the unevenness is provided in the extending portion.

The prevention of the peeling of the transparent resin body 17 on the upper surface side of the leadframes 11 and 12 by providing the trenches 71b to 71e and 72b to 72e in the upper surfaces of the leadframes 11 and 12 on which a component that functions as a light emitting unit configured to emit light to the outside is provided is effective to suppress degradation and/or fluctuation of the light emission characteristics.

The trenches 71b to 71e and 72b to 72e can be made more easily by etching. Unlike stamping, the etching does not apply a mechanical load to the leadframes 11 and 12. Thereby, the damage, the configurational degradation, and the dimensional fluctuation of the leadframes 11 and 12 can be suppressed.

In the embodiments described above, the LED chip is not limited to the structure in which two terminals are provided on the upper surface. One terminal may be provided on the lower surface; and the one terminal may be bonded to one of the leadframes by face-down bonding. Alternatively, two terminals may be provided on the lower surface; and the two terminals may be bonded to the first leadframe and the second leadframe respectively by face-down bonding. Multiple LED chips may be mounted to one LED package.

The LED chip is not limited to a chip configured to emit blue light. The phosphor is not limited to a phosphor configured to absorb blue light and emit yellow light. The LED chip may emit visible light of a color other than blue and may emit ultraviolet or infrared. The phosphor may be a phosphor configured to emit blue light, green light, or red light.

The color of the light that the entire LED package emits is not limited to white. Any color tone can be realized by adjusting the weight ratio R:G:B of the red phosphor, the green phosphor, and the blue phosphor such as those described above. For example, a white emitted light having a color from white lamp to white fluorescent lamp can be realized by an R:G:B weight ratio of one selected from 1:1:1 to 7:1:1, 1:1:1 to 1:3:1, and 1:1:1 to 1:1:3. The phosphor may not be provided in the LED package. In such a case, the light emitted from the LED chip is emitted from the LED package.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An LED package, comprising:
mutually-separated first and second leadframes disposed on a plane;
an LED chip provided above the first and second leadframes, one terminal of the LED chip being connected to the first leadframe, one other terminal of the LED chip being connected to the second leadframe; and
a resin body covering the LED chip, the resin body covering an upper surface, a portion of a lower surface and a portion of an end surface of the first leadframe, and an upper surface, a portion of a lower surface and a portion of an end surface of the second leadframe, a remaining portion of the lower surface and a remaining portion of the end surface of the first leadframe being exposed from the resin body, a remaining portion of the lower surface and a remaining portion of the end surface of the second leadframe being exposed from the resin body,
one selected from the first leadframe and the second leadframe including:
a base portion having an end surface covered with the resin body; and
an extending portion extending from the base portion and having an unevenness provided in a surface of the extending portion, a lower surface of the extending portion being covered with the resin body, a tip surface of the extending portion being exposed from the resin body,
an exterior form of the resin body being used as an exterior form of the LED package.

2. The LED package according to claim 1, wherein a protrusion is formed in a region of one selected from the lower surface of the first leadframe and the lower surface of the second leadframe, the region is separated from the other selected from the lower surface of the first leadframe and the lower surface of the second leadframe, a lower surface of the protrusion is exposed at a lower surface of the resin body, and a side surface of the protrusion is covered with the resin body.

3. The LED package according to claim 1, wherein three of the extending portions extend from the base portion in mutually different directions, and the unevenness is provided in at least one of the extending portions.

4. The LED package according to claim 1, wherein the tip surfaces of a plurality of the extending portions are exposed at three mutually different side surfaces of the resin body, and the unevenness is provided in one of the extending portions.

5. The LED package according to claim 1, wherein the base portion is not exposed at a side surface of the resin body.

6. The LED package according to claim 1, wherein the resin body is filled into a recess of the unevenness provided in the extending portion.

7. The LED, package according to claim 1, wherein the unevenness is provided in the lower surface of the extending portion.

8. The LED package according to claim 2, wherein the unevenness is provided in the lower surface of the extending portion, and a protrusion of the unevenness has a protruding length shorter than a protruding length of the protrusion of the one selected from the lower surface of the first leadframe and the lower surface of the second leadframe.

9. The LED package according to claim 8, wherein a lower surface of the protrusion of the unevenness is covered with the resin body.

10. The LED package according to claim 1, wherein a recess sunken with respect to the upper surface of the extending portion is provided.

11. The LED package according to claim 1, wherein:
recesses are provided respectively in an upper surface and the lower surface of the extending portion; and
a planar-direction position of the recess provided in the upper surface of the extending portion is shifted from a planar-direction position of the recess provided in the lower surface of the extending portion.

12. An LED package, comprising:
mutually-separated first and second leadframes disposed on a plane;
an LED chip provided above the first and second leadframes, one terminal of the LED chip being connected to the first leadframe, one other terminal of the LED chip being connected to the second leadframe; and
a resin body covering the LED chip, the resin body covering an upper surface, a portion of a lower surface and a portion of an end surface of the first leadframe, and an upper surface, a portion of a lower surface and a portion of an end surface of the second leadframe, a remaining portion of the lower surface and a remaining portion of the end surface of the first leadframe being exposed from the resin body, a remaining portion of the lower surface and a remaining portion of the end surface of the second leadframe being exposed from the resin body,
one selected from the first leadframe and the second leadframe including:
a base portion having an end surface covered with the resin body; and
an extending portion extending from the base portion, a lower surface of the extending portion being covered with the resin body, a tip surface of the extending portion being exposed from the resin body,
an upper surface of the extending portion and an upper surface of the base portion being disposed on a plane, a trench being provided between the upper surface of the extending portion and the upper surface of the base portion, an exterior form of the resin body being used as an exterior form of the LED package.

13. The LED package according to claim 12, wherein a protrusion is formed in a region of one selected from the lower surface of the first leadframe and the lower surface of the second leadframe, the region is separated from the other selected from the lower surface of the first leadframe and the lower surface of the second leadframe, a lower surface of the protrusion is exposed at a lower surface of the resin body, and a side surface of the protrusion is covered with the resin body.

14. The LED package according to claim 12, wherein three of the extending portions extend from the base in mutually different directions, and the trench is provided between the upper surface of one of the extending portions and the upper surface of the base portion.

15. The LED package according to claim 12, wherein the tip surfaces of a plurality of the extending portions are exposed at three mutually different side surfaces of the resin body, and the trench is provided between the upper surface of at least one of the extending portions and the upper surface of the base portion.

16. The LED package according to claim 12, wherein the base portion is not exposed at a side surface of the resin body.

17. The LED package according to claim 12, wherein the resin body is filled into the trench.
